(19) United States
(12) Patent Application Publication
(10) Pub. No.: US 2009/0256192 A1
(43) Pub. Date: Oct. 15, 2009

(54) NONVOLATILE SEMICONDUCTOR MEMORY DEVICE AND METHOD OF MANUFACTURING THE SAME

(76) Inventors: Ryota FUJITSUKA, Yokohama-shi (JP); Katsuyuki SEKINE, Yokohama-shi (JP); Daisuke NISHIDA, Yokkaichi-shi (JP); Katsuaki NATORI, Yokohama-shi (JP); Yoshio OZAWA, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/407,597

(22) Filed: Mar. 19, 2009

(30) Foreign Application Priority Data
Apr. 11, 2008 (JP) 2008-103541

(51) Int. Cl. H01L 29/792; H01L 21/762; H01L 21/336

(52) U.S. Cl. 257/324; 438/424; 257/E29.309; 257/E21.546; 257/E21.423

(57) ABSTRACT

In a nonvolatile semiconductor memory device where a tunnel insulating film, a charge storage layer, a blocking insulating film, and a control gate are stacked one on top of another on a semiconductor substrate, with an element isolation insulating film buried between adjacent cells, a barrier layer composed of at least one of a silicon nitride film, a silicon oxynitride film, and a silicon oxide film which has a higher density than that of the element isolation insulating film is provided at the interface between the element isolation insulating film and the blocking insulating film or between the element isolation film and the control gate.

### CROSS-REFERENCE TO RELATED APPLICATIONS

This application is based upon and claims the benefit of priority from prior Japanese Patent Application No. 2008-103541, filed Apr. 11, 2008, the entire contents of which are incorporated herein by reference.

### BACKGROUND OF THE INVENTION

1. Field of the Invention

This invention relates to a nonvolatile semiconductor memory device using an insulating film as a charge storage layer, and more particularly to a nonvolatile semiconductor memory device with an improved memory cell structure and a method of manufacturing the nonvolatile semiconductor memory device.

2. Description of the Related Art

In recent years, a MONOS using an insulating film, such as a silicon nitride film, as a charge storage layer has been developed as one of the nonvolatile semiconductor memory devices. The MONOS is so configured that a charge storage layer is formed on a tunnel insulating film above a semiconductor substrate, then a blocking insulating film is formed on the charge storage layer, and a control gate is formed on the blocking insulating film. The adjacent memory cells are separated by an element isolation insulating film, such as a silicon oxide film. Moreover, the charge storage layer is also separated between adjacent cells (refer to, for example, Jpn. Pat. Appln. KOKAI Publication No. 2002-100686 and Jpn. Pat. Appln. KOKAI Publication No. 2004-153049).

However, this type of MONOS has the following problem: when a blocking insulating film is deposited, impurities, including carbon and nitrogen, diffuse easily into the element isolation insulating film through the lower interface of the blocking insulating film. They act as fixed charges, which degrades the transistor characteristics of the memory cells. Moreover, when the annealing especially in the oxidized gas-containing ambient is done, the active oxidant easily diffuse into the element isolation insulating film, through the lower interface of the blocking insulating film. Then, it induces a bird's beak in the tunnel insulating film, which causes the write/erase characteristics degradation.

To suppress charge transfer in the charge storage layer between adjacent cells, the following method is effective: elements are isolated after a blocking insulating film has been deposited and both the charge storage layer and the blocking insulating layer are separated by element isolation insulating films between adjacent cells. In this case, too, a problem arises: when a control gate electrode is deposited, impurities, including carbon and nitrogen, easily diffuse through the interface between the control gate electrode and the element isolation insulating film into the element isolation insulating film, which degrades the transistor characteristics of the memory cells for the same reason as described above.

### BRIEF SUMMARY OF THE INVENTION

According to an aspect of the invention, there is provided a nonvolatile semiconductor memory device comprising: a semiconductor substrate with an element forming region; a charge storage layer which is composed of an insulating film and which is provided on a tunnel insulating film above the element forming region of the substrate; a blocking insulating film which is provided on the charge storage layer; an element isolation insulating film which is buried in the substrate so as to isolate adjacent element forming regions and which is provided so as to isolate the charge storage layer or the charge storage layer and blocking insulating film; a control gate which is provided on the blocking insulating film; and a barrier layer which is provided between the element isolation insulating film and the blocking insulating film or the control gate and which is composed of at least one of a silicon nitride film, a silicon oxynitride film, and a silicon oxide film, which has a higher density than that of a silicon oxide film constituting the element isolation insulating film.

According to another aspect of the invention, there is provided a nonvolatile semiconductor memory device manufacturing method comprising: forming a tunnel insulating film on a semiconductor substrate; forming a charge storage layer composed of an insulating film on the tunnel insulating film; not only selectively etching the charge storage layer and tunnel insulating film between adjacent element forming regions of the substrate but also etching the surface part of the substrate, thereby forming an element isolation trench; forming an element isolation insulating film so as to fill up the element isolation trench; forming on at least the element isolation insulating film a barrier layer composed of at least one of a silicon nitride film, a silicon oxynitride film, and a silicon oxide film each having a higher density than that of a silicon oxide film constituting the element isolation insulating film; forming on the element isolation insulating film and charge storage layer, a blocking insulating film at the interface with at least the element isolation insulating film so as to sandwich the barrier layer between the element isolation insulating film and the blocking insulating film; and forming a control gate on the blocking insulating film.

According to still another aspect of the invention, there is provided a nonvolatile semiconductor memory device manufacturing method comprising: forming a tunnel insulating film on a semiconductor substrate; forming a charge storage layer composed of an insulating film on the tunnel insulating film; forming a blocking insulating film on the charge storage layer; not only selectively etching the blocking insulating film, charge storage layer, and tunnel insulating film between adjacent element forming regions of the substrate but also etching the surface part of the substrate, thereby forming an element isolation trench; forming an element isolation insulating film so as to fill up the element isolation trench; forming on at least the element isolation insulating film a barrier layer composed of at least one of a silicon nitride film, a silicon oxynitride film, and a silicon oxide film each having a higher density than that of a silicon oxide film constituting the element isolation insulating film; and forming on the element isolation insulating film and blocking insulating film, a control gate film at the interface with at least the element isolation insulating film so as to sandwich the barrier layer between the element isolation insulating film and the control gate.

### BRIEF DESCRIPTION OF THE SEVERAL VIEWS OF THE DRAWING

FIG. 1 is a sectional view taken in the word line direction (or channel width direction) to explain the element structure of a nonvolatile semiconductor memory according to a first embodiment of the invention;

FIG. 2 is a sectional view taken in the bit line direction (or channel length direction) to explain the element structure of the nonvolatile semiconductor memory according to the first embodiment;

FIGS. 3A to 3G are sectional views to help explain the process of manufacturing a nonvolatile semiconductor memory according to the first embodiment;

FIG. 4 is a sectional view of a modification of the first embodiment;

FIG. 5 is a sectional view taken in the word line direction (or channel width direction) to explain the element structure of a nonvolatile semiconductor memory according to a second embodiment of the invention;

FIG. 6 is a sectional view taken in the bit line direction (or channel length direction) to explain the element structure of the nonvolatile semiconductor memory according to the second embodiment;

FIGS. 7A to 7C are sectional views to help explain the process of manufacturing a nonvolatile semiconductor memory according to the second embodiment;

FIG. 8 is a sectional view taken in the word line direction (or channel width direction) to explain the element structure of a nonvolatile semiconductor memory according to a third embodiment of the invention;

FIG. 9 is a sectional view taken in the bit line direction (or channel length direction) to explain the element structure of the nonvolatile semiconductor memory according to the third embodiment;

FIGS. 10A to 10F are sectional views to help explain the process of manufacturing a nonvolatile semiconductor memory according to the third embodiment;

FIG. 11 is a sectional view of a modification of the invention;

FIG. 12 is sectional view showing the cell structure of a conventional MONOS nonvolatile semiconductor memory; and

FIG. 13 is a sectional view showing the cell structure of a general MONOS nonvolatile semiconductor memory.

### DETAILED DESCRIPTION OF THE INVENTION

Before the explanation of embodiments of the invention, a conventional MONOS structure will be described as a comparative example.

FIGS. 12 and 13 are sectional views showing the element structure of a general MONOS nonvolatile semiconductor memory device. In FIGS. 12 and 13, numeral 10 indicates a silicon substrate, 11 a tunnel insulating film, 12 a charge storage layer, 13 an element isolation insulating film (STI), 15 a blocking insulating film, and 16 a control gate electrode.

The structure of FIG. 12 is realized by separating elements after the deposition of the charge storage layer 12 and isolating the charge storage layer 12 between adjacent cells with the element isolation insulating film 13. With this structure, when an insulating film including elemental aluminum or a transition metal, such as hafnium, zirconium, titanium, or lanthanum, is deposited as the blocking insulating film 15, if a source gas including impurities, such as carbon or nitrogen is used, the impurities diffuse easily into the element isolation insulating film 13. The diffused impurities act as fixed charges, which causes the transistor characteristics of the memory cells to deteriorate.

Furthermore, even when the blocking insulating film 15 is deposited in an atmosphere including oxidized gas or when heat treatment is performed in an atmosphere including oxidized gas after the deposition of the blocking insulating film 15, the oxidant easily diffuses into the element isolation insulating film 13. Then, it induces a bird's beak in the tunnel insulating film 11, which causes the write/erase characteristics degradation.

In the structure of FIG. 13, each memory cells are separated after the deposition of the blocking insulating film 15 and both the charge storage layer 12 and the blocking insulating film 15 are isolated between adjacent cells with the element isolation insulating film 13. However, when material including elemental aluminum or a transition metal, such as tantalum, tungsten, or titanium, is used as the control gate electrode 16, if the control gate electrode 16 is deposited using a source gas including impurities, such as carbon or nitrogen, the impurities diffuse easily into the element isolation insulating film 13. For the same reason described above, this causes the transistor characteristics of the memory cells to deteriorate.

In embodiments of the invention, to solve the problems, a barrier layer for blocking impurities and oxidizing agent is provided at the interface between the element isolation insulating film and the blocking insulating film or between the element isolation insulating film and the control gate electrode in the cell structure of a nonvolatile semiconductor memory using an insulating film as the charge storage layer.

Hereinafter, referring to the accompanying drawings, embodiments of the invention will be explained.

### First Embodiment

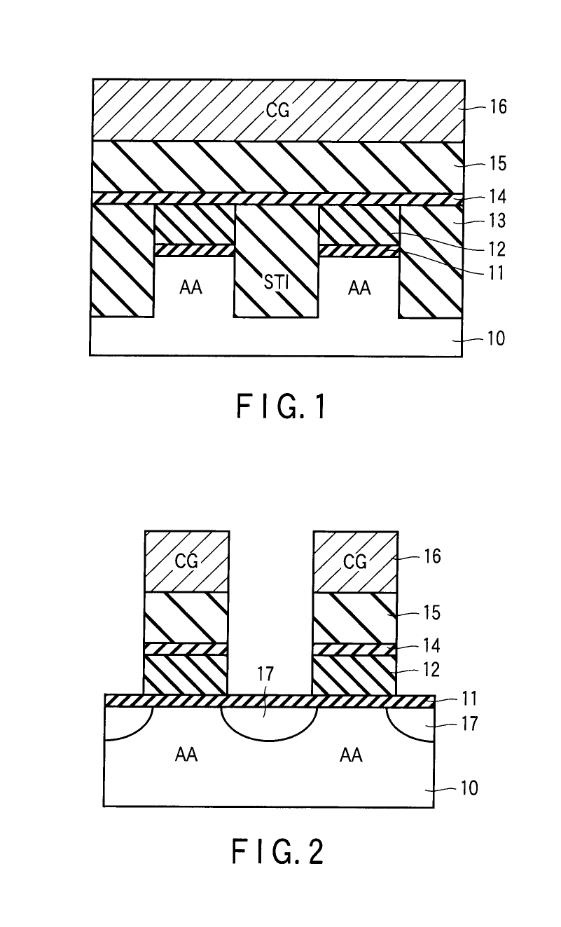

FIGS. 1 and 2 are sectional views showing the element structure of a nonvolatile semiconductor memory device according to a first embodiment of the invention. FIG. 1 is a sectional view taken in the word line direction (or channel width direction). FIG. 2 is a sectional view taken in the bit line direction (or channel length direction).

On the surface of a silicon substrate (or semiconductor substrate) 10, there is provided an element forming region (AA) enclosed by an element isolation insulating film (STI), such as a silicon oxide film. Above the element forming region (AA), there is provided a charge storage layer 12 composed of a silicon nitride film on a tunnel insulating film 11, such as a silicon oxide film. On the element isolation insulating film 13 and charge storage layer 12, a barrier layer 14 composed of a silicon nitride film is provided. On the barrier layer 14, there are provided a blocking insulating film 15, such as alumina, and a control gate electrode (CG) 16, such as tungsten silicide.

As shown in FIG. 2, the charge storage layer 12, barrier layer 14, blocking insulating film 15, and control gate electrode 16 are isolated between adjacent cells in the channel length direction. At the surface of the substrate 10, source/drain regions 17 are formed on both sides of the memory cell. As shown in FIG. 1, the tunnel insulating film 11 and charge storage layer 12 are isolated between adjacent cells in the channel width direction by the element isolation insulating film 13. The barrier layer 14, blocking insulating film 15, and control gate electrode 16 are formed continuously in the channel width direction.

As described above, the first embodiment differs from the conventional equivalent in that the barrier layer 14 composed of a silicon nitride film has been formed at the interface between the blocking insulating film 15 and the element isolation insulating film 13 and charge storage layer 12. More specifically, the barrier layer 14 composed of a silicon nitride film has been inserted into the interface between the blocking insulating film 15 and element isolation insulating film 13.

In each of the memory cells of the first embodiment, a high voltage is applied between the substrate and the control gate electrode 16, thereby applying an intense electric field to the tunnel insulating film 11, which causes a tunnel current to flow. Then, the amount of charges captured in the charge storage layer 12 is changed, thereby performing a data write (or erase) operation. In FIG. 2, only two memory cells are shown. Actually, however, a lot of memory cells are arranged in the word line direction and in the bit line direction.

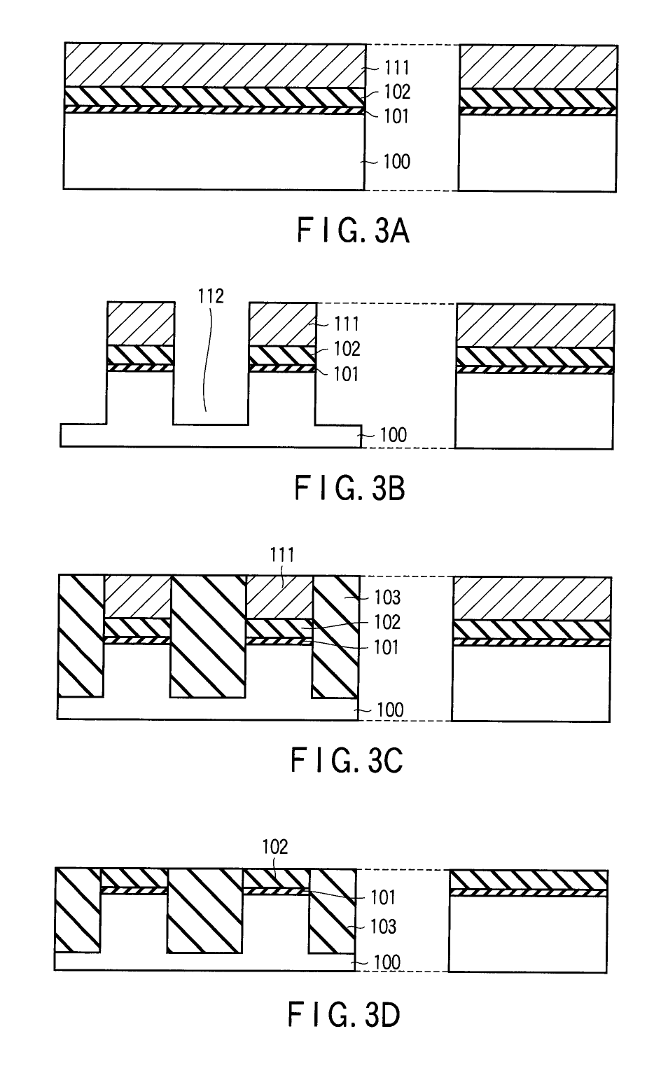

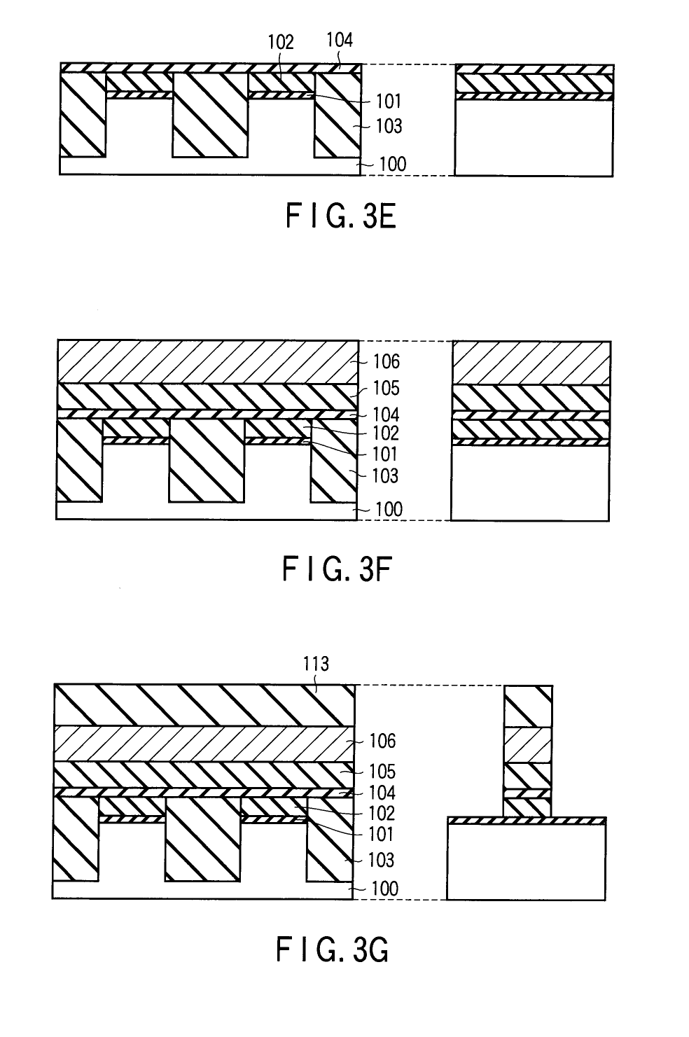

Next, a method of manufacturing a nonvolatile semiconductor memory of the first embodiment will be explained with reference to FIGS. 3A to 3G. In FIGS. 3A to 3G, sectional views taken in the channel width direction are shown on the left side and sectional views taken in the channel length direction are shown on the right side.

First, as shown in FIG. 3A, on the surface of a silicon substrate (or semiconductor substrate) 100 doped with a desired impurity, a 3-nm-thick silicon oxide film 101 is formed as a tunnel insulating film 11 by a thermal oxidation method. Then, on the silicon oxide film 101, a 10-nm-thick silicon nitride film 102 to act as a charge storage layer 12 is deposited by CVD techniques. Thereafter, on the silicon nitride film 102, an amorphous silicon film to serve as a mask material 111 for element isolation is deposited by CVD techniques.

Next, as shown in FIG. 3B, the mask material 111, silicon nitride film 102, and silicon oxide film 101 are etched sequentially by reactive ion etching (RIE) techniques using a first resist mask (not shown). Then, the exposed region of the silicon substrate 100 is etched, thereby making a 100-nm-deep element isolation trench 112.

Next, as shown in FIG. 3C, an element isolation silicon oxide film 103 is deposited on the entire surface by CVD techniques, thereby filling up the element isolation trench 112 with the silicon oxide film 103 completely. Then, the silicon oxide film 103 at the surface is removed by chemical mechanical polishing (CMP) techniques, thereby planarizing the surface. At this time, the top surface of the mask material 111 is exposed.

Next, as shown in FIG. 3D, after the exposed mask material 111 is selectively etched with a chemical solution or the like, the exposed surface of the silicon oxide film 103 is etched so as to be as high as the surface of the silicon nitride film 102.

Next, as shown in FIG. 3E, a silicon nitride film 104 to act as a barrier layer 14 is deposited to a thickness of 2 nm on the surface of the silicon nitride film 102 serving as the charge storage layer 12 and on the surface of the silicon oxide film 103 serving as the element isolation insulating film 13 by ALD techniques using dichlorosilane as a silicon source and ammonia radical as a nitriding agent.

Next, as shown in FIG. 3F, on the silicon nitride film 104 acting as the barrier layer 14, an alumina film 105 to serve as the blocking insulating film 15 is deposited to a thickness of 20 nm by ALD techniques using trimethylaluminum and water vapor as raw material gases. Then, a 100-nm-thick conducting layer 106 with a two-layer structure composed of a polysilicon layer/tungsten silicide layer to act as a control gate electrode 16 is deposited sequentially by CVD techniques.

Here, the reason why alumina is used as the blocking insulating film 15 is to obtain high permittivity. As the material for the high-permittivity blocking insulating film 15, not only an insulating film including elemental aluminum, such as alumina, but also an insulating film including a transition metal, such as hafnium, zirconium, titanium, or lanthanum, may be used. When such a blocking insulating film 15 is deposited, even if a source gas including impurities, such as carbon or nitrogen, is used, the presence of the barrier layer 14 suppresses the diffusion of the impurities into the element isolation insulating film 13.

The reason why the two-layer structure composed of a polysilicon layer/tungsten silicide layer is used as the control gate electrode 16 is to decrease resistance. As the material for the low-resistance control gate electrode 16, a conducting layer including elemental aluminum or a transition metal, such as tantalum, tungsten, or titanium, may be used. When such a control gate electrode 16 is deposited, even if a source gas including impurities, such as carbon or nitrogen, is used, the presence of the barrier layer 14 suppresses the diffusion of the impurities into the element isolation insulating film 13.

Next, as shown in FIG. 3G, a silicon nitride film 113 to act as a mask material for RIE is deposited by CVD techniques. Then, by RIE techniques using a second resist mask (not shown) having a pattern perpendicular to the first resist mask, the mask material 113, the conducting layer to act as the control gate electrode 16, the alumina film 105 to act as the blocking insulating film 15, the silicon nitride film 104 to act as the barrier layer 14, and the silicon nitride film 102 to serve as the charge storage layer 12 are etched sequentially, thereby forming a gate electrode part. At this time, the width of the silicon nitride film 102 to serve as the charge storage layer 12 and the spacing between adjacent silicon nitride layers 12 are both set to about 40 nm.

Although not shown from this point on, a 10-nm-thick gate sidewall oxide film is formed on the sidewalls of the control gate electrode 16, blocking insulating film 15, and charge storage layer 12 by a combination of the thermal oxidation and CVD techniques. Thereafter, by ion implantation techniques and thermal annealing techniques, an impurity diffused layer to act as a source-drain region 17 is formed. Then, an interlayer insulating film is formed by CVD techniques or the like. Then, an interconnect layer and other elements (not shown) are formed by known techniques, which completes a nonvolatile semiconductor memory.

As described above, in the nonvolatile semiconductor memory device of the first embodiment, since the charge storage layer 12 is isolated at the cross section in the channel width direction by the element isolation insulating film 13, a fluctuation in the threshold voltage of the memory cells caused by charge diffusion between adjacent cells can be suppressed. The barrier layer 14 provided at the interface between the blocking insulating film 15 and the element isolation insulating film 13 can suppress the diffusion of impurities into the STI (insulating film 13), even if the source gas including carbon or nitrogen was used, during the blocking insulating film 15 (including elemental aluminum or a transition metal, such as hafnium, zirconium, titanium, or lanthanum) deposition. This suppresses the deterioration of the transistor characteristics of the memory cells, realizing the desired transistor characteristics.

Furthermore, the barrier layer 14 provided at the interface between the blocking insulating film 15 and the element isolation insulating film 13 can prevent the oxidant from diffusing into the element isolation insulating film 13 when the blocking insulating film 15 is formed in an atmosphere including oxidized gas or when post-heating is done in an atmosphere including oxidized gas. This suppresses the bird's beak formation in the tunnel insulating film 11, which attains the desired write/erase characteristics.

In the first embodiment, the barrier layer 14 composed of a silicon nitride film has been deposited to a thickness of 2 nm at the interface between the blocking insulating film 15 and the element isolation insulating film 13. As the barrier layer 14 becomes thicker, the barrier properties against the impurities, such as carbon or nitrogen, from the blocking insulating film 15 and the diffusion barrier properties against the oxidant are improved more. However, when the film thickness is 5 nm or more, a fluctuation in the threshold voltage of memory cells caused by charge movement between adjacent cells becomes significant. Therefore, it is desirable that the thickness of the silicon nitride film of the barrier layer 14 should be not less than 1 nm and not more than 5 nm.

While in the above manufacturing method, the ALD techniques using dichlorosilane as a silicon source and ammonia radical have been used in depositing the silicon nitride film 104 serving as the barrier layer 14, other raw material gases may be used in depositing the silicon nitride film. The ALD techniques are favorable as a method of forming an interface barrier silicon nitride film layer in the first embodiment since the film thickness can be controlled accurately even in the thin-film region and the film can be deposited so as to produce a good morphology even on the element isolation insulating film 13. The same effect can be produced even by forming the silicon nitride film 104 by another method, such as LPCVD techniques or radical nitriding techniques.

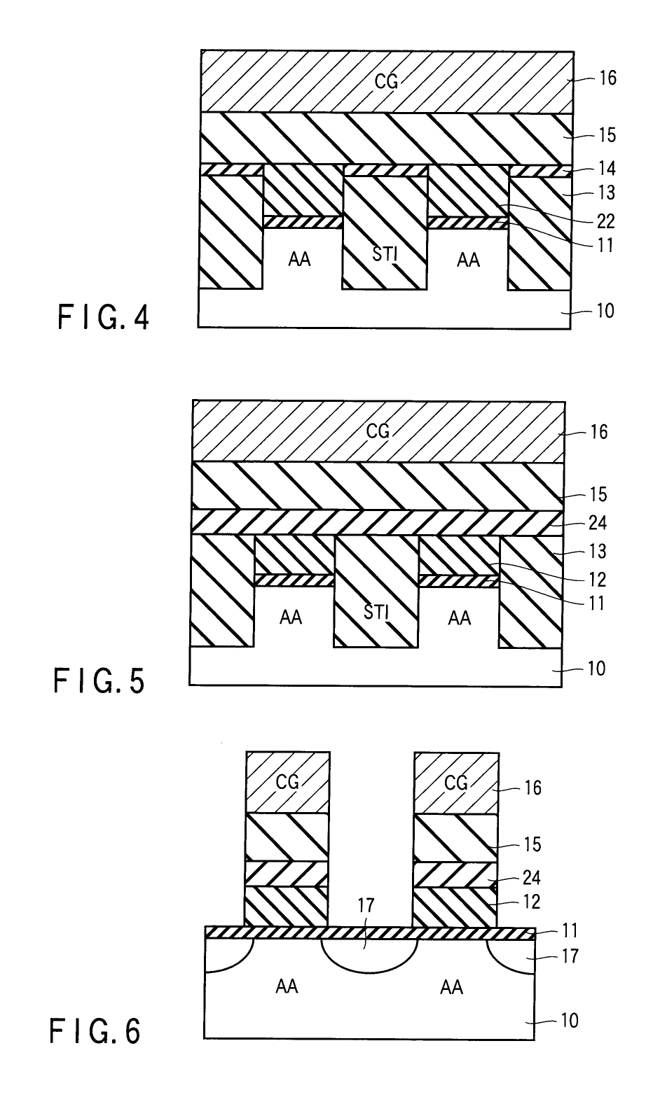

In the radical nitriding techniques, when a material other than a silicon nitride film (e.g., an oxide including hafnium) is applied to the charge storage layer 22 as shown in FIG. 4, a barrier layer 14 composed of a silicon oxynitride film is formed only on the element isolation insulating film 13. This is because the element isolation insulation film 13 consisting of the silicon dioxide film surface is nitrided. In this case, the charge trapping energy level of the barrier layer 14 is different from that of the charge storage layer 22, the charges in the charge storage layer 22 are less liable to pass through the barrier layer 14 into adjacent cells. Therefore, a much better threshold fluctuation suppressing effect can be obtained.

### Second Embodiment

FIGS. 5 and 6 are sectional views showing the element structure of a nonvolatile semiconductor memory device according to a second embodiment of the invention. FIG. 5 is a sectional view taken in the word line direction (or channel width direction). FIG. 6 is a sectional view taken in the bit line direction (or channel length direction). The same parts as those in FIGS. 1 and 2 are indicated by the same reference numerals and a detailed explanation of them will be omitted.

The second embodiment differs from the first embodiment in that a silicon oxide film whose density is higher than that of the silicon oxide film of the element isolation insulating film 13 is used as the barrier layer in place of the silicon nitride film.

As in the first embodiment, on the surface of a silicon substrate 10, there is provided an element forming region (AA) enclosed by an element isolation insulating film (STI) 13 composed of a silicon oxide film. Above the element forming region (AA), there is provided a charge storage layer 12 via a tunnel insulating film 11. On the element isolation insulating film 13 and charge storage layer 12, there is provided a barrier layer 24 composed of a silicon oxide film whose density is higher than that of the silicon oxide film of the element isolation insulating film 13. On the barrier layer 24, there are provided a blocking insulating film 15 and a control gate electrode (CG) 16.

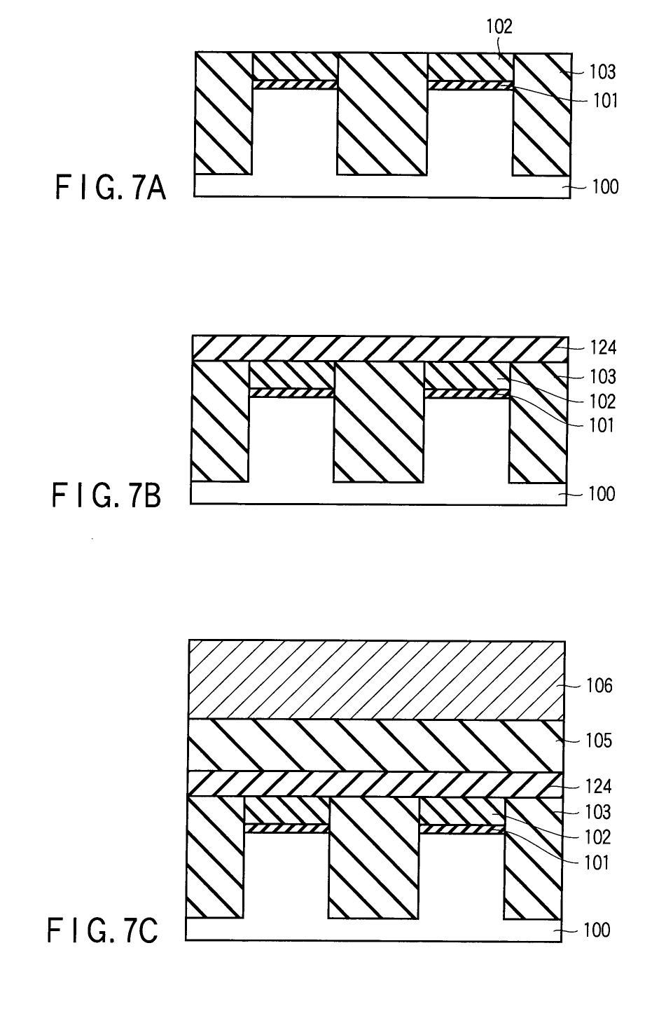

Next, a method of manufacturing a nonvolatile semiconductor memory device of the second embodiment will be explained with reference to FIGS. 7A to 7C. FIGS. 7A to 7C are sectional views taken in the channel width direction.

The processes up to that in FIG. 3D are the same as those in the first embodiment. As shown in FIG. 7A, on the surface of a silicon substrate 100, a silicon nitride film 102 to serve as a charge storage layer 12 is formed via a tunnel oxide film 101 acting as a tunnel insulating film 11 and a silicon oxide film 103 serving as the element isolation insulating film 13 formed so as to be buried between adjacent cells.

Next, as shown in FIG. 7B, on the silicon oxide film 103 and silicon nitride film 102, a silicon oxide film 124 serving as the barrier layer 24 is deposited to a thickness of 5 nm by ALD techniques using trisdimethylaminosilane (TDMAS) as a silicon source and ozone as an oxidizing agent. Then, heat treatment is performed in a nitrogen atmosphere at 900° C., thereby densifying the silicon oxide film 124.

Then, as shown in FIG. 7C, on the silicon oxide film 124 serving as the barrier layer 24, an alumina film 105 to serve as a blocking insulating film 15 is deposited to a thickness of 15 nm by ALD techniques using trimethylaluminum and water vapor as raw material gases. Then, a 100-nm-thick conducting layer 106 with a two-layer structure composed of a polysilicon layer/tungsten silicide layer to act as a control gate electrode 16 is deposited sequentially by CVD techniques.

From this point on, the conducting layer 106, alumina film 105, silicon oxide film 124, and silicon nitride film 102 are etched sequentially as in the first embodiment, thereby forming a gate electrode part and further forming an impurity diffused layer to serve as a source-drain region 17, which completes a nonvolatile semiconductor memory device with the structure shown in FIGS. 5 and 6.

As described above, with the second embodiment, the barrier layer 24 composed of a silicon oxide film whose density is higher than that of the element isolation insulating film 13 has been provided at the interface between the blocking insulating film 15 and the element isolation insulating film 13, which suppresses the diffusion of impurities into the element isolation insulating film 13 caused by the formation of the blocking insulation insulating film 14. Accordingly, the same effect as that of the first embodiment can be obtained. Moreover, use of a silicon oxide film as the barrier layer 24 enables charges trapped in the barrier layer 24 to be reduced, decreasing the diffusion of carrier adjacent cells more than in the first embodiment, which achieves a much better threshold voltage fluctuation suppressing effect.

In the second embodiment, the barrier layer 24 composed of a silicon oxide film has been deposited to a thickness of 5 nm at the lower interface of the blocking insulating film 15. As the barrier layer 24 gets thicker, the diffusion of impurities, such as carbon or nitrogen, into the element isolation insulating film 13 can be suppressed more during the blocking insulating film 15 deposition. Moreover, as the high-density silicon oxide film gets thicker, the diffusion barrier properties against the oxidant are improved more. However, if the thickness of the silicon oxide film is increased to 10 nm or more, making the total EOT (Equivalent Oxide Thickness) thicker, which causes the write/erase characteristics degradation. Therefore, it is desirable that the thickness of the silicon oxide film should be not thicker than 10 nm.

While in the above manufacturing method, the ALD techniques using TDMAS as a silicon source and ozone as an oxidant agent have been used in depositing a silicon oxide film serving as the barrier layer 24, other raw material gases may be used. Moreover, even when a silicon oxide film is formed by another method, such as LPCVD techniques, the same effect is obtained, provided that the silicon oxide film has a higher density than the element isolation silicon oxide film. Although heat treatment has been performed at 900° C. to densify the silicon oxide film, heat treatment may not be performed, provided that the silicon oxide film has a higher density than the element isolation silicon oxide film at the time of deposition. If the density is low at the time of deposition, the silicon oxide film is densified more as the heat treatment temperature gets higher. When the heat treatment temperature is 1110° C. or higher, the reliability of the memory cells decreases due to the thermal damage deterioration of the tunnel oxide film. Therefore, it is desirable that the densifying heat treatment should be performed at not lower than 800° C. and not higher than 1100° C.

Furthermore, while in the second embodiment, the barrier layer 24 has been formed between the element isolation insulating film 13 and charge storage layer 12 and the blocking insulating film 15, the point is to suppress the diffusion of impurities, such as carbon or nitrogen, from the blocking insulating film 15 into the element isolation insulating film 13. Accordingly, as in the example of FIG. 4 of the first embodiment, the barrier layer 24 may be formed only between the element isolation insulating film 13 and the blocking insulating film 15.

### Third Embodiment

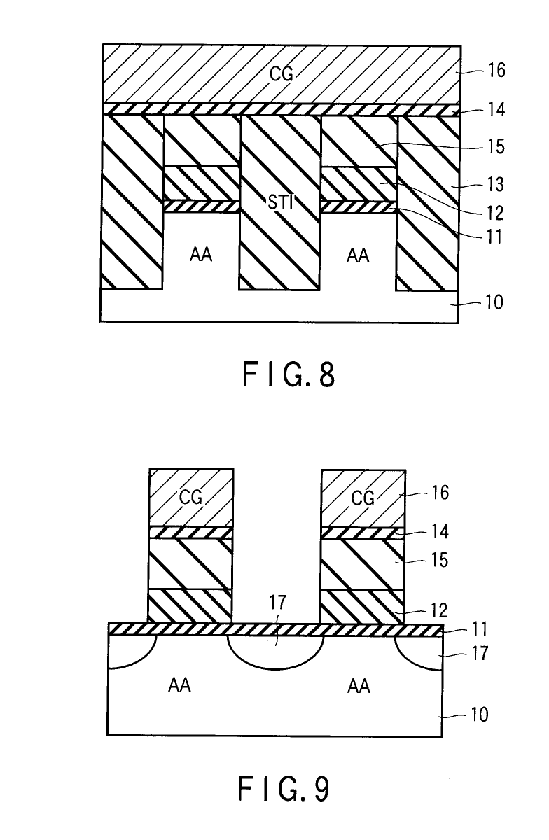

FIGS. 8 and 9 are sectional views showing the element structure of a nonvolatile semiconductor memory device according to a third embodiment of the invention. FIG. 8 is a sectional view taken in the word line direction (or channel width direction). FIG. 9 is a sectional view taken in the bit line direction (or channel length direction). The same parts as those in FIGS. 1 and 2 are indicated by the same reference numerals and a detailed explanation of them will be omitted.

The third embodiment differs from the first embodiment in that not only the charged storage layer but also the blocking insulating film is isolated between adjacent cells.

On the surface of a silicon substrate (or semiconductor substrate) 10, there is provided an element forming region (AA) enclosed by an element isolation insulating film (STI) 13. Above the element forming region (AA), there is provided a charge storage layer 12 composed of a silicon nitride film on a tunnel insulating film 11. On the charge storage layer 12, a blocking insulating film 15 is provided. On the element isolation insulating film 13 and blocking insulating film 15, a barrier layer 14 composed of a silicon nitride film is provided. On the barrier layer 14, a control gate electrode (CG) 16 is provided.

As shown in FIG. 9, the charge storage layer 12, blocking insulating film 15, barrier layer 14, and control gate electrode 16 are isolated between adjacent cells in the channel length direction. At the surface of the substrate 10, source/drain regions 17 are formed on both sides of the memory cell. As shown in FIG. 8, the tunnel insulating film 11, charge storage layer 12, and blocking layer 15 are isolated between adjacent cells in the channel width direction by the element isolation insulating film 13. The barrier layer 14 and control gate electrode 16 are formed continuously in the channel width direction.

That is, the tunnel insulating film 11, charge storage layer 12, and blocking layer 15 are isolated between adjacent cells in the channel width direction by the element isolation insulating film 13, with the barrier layer 14 existing at the interface between the control gate electrode 16 and the element isolation insulating film 13.

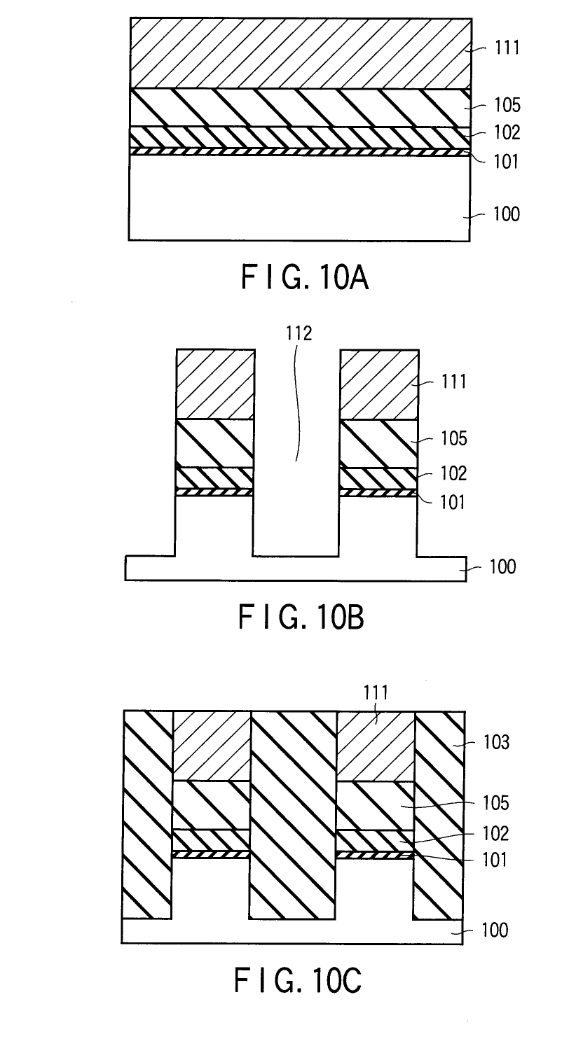

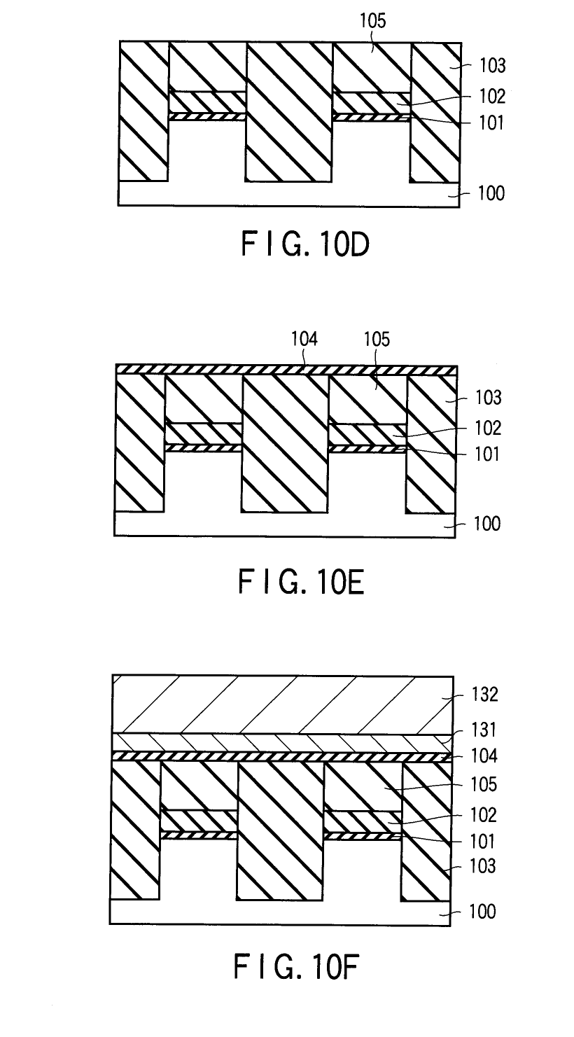

Next, a method of manufacturing a nonvolatile semiconductor memory device of the third embodiment will be explained with reference to FIGS. 10A to 10F. FIGS. 10A to 10F are sectional views taken in the channel width direction.

First, as shown in FIG. 10A, on the surface of a silicon substrate (or semiconductor substrate) 100 doped with desired impurities, a 3-nm-thick tunnel oxide film 101 is formed as a tunnel insulating film 11 by a thermal oxidation method. Then, on the tunnel oxide film 101, a 10-nm-thick silicon nitride film 102 to serve as a charge storage layer 12 is deposited by CVD techniques. Then, on the silicon nitride film 102, an alumina film 105 to act as a blocking insulating film 15 is deposited to a thickness of 20 nm by ALD techniques using trimethylaluminum and water vapor as raw material gases. Thereafter, on the alumina film 105, a silicon nitride film 111 to serve as a mask material for element isolation is deposited by CVD techniques.

Next, as shown in FIG. 10B, the mask material 111, alumina film 105, silicon nitride film 102, and silicon oxide film 101 are etched sequentially by RIE techniques using a first resist mask (not shown). Then, the exposed region of the silicon substrate 100 is etched, thereby forming a 100-nm-deep element isolation trench 112.

Next, as shown in FIG. 10C, an element isolation silicon oxide film 103 is deposited on the entire surface by CVD techniques, thereby filling up the element isolation trench 112 with a silicon oxide film 103 completely. Then, the silicon oxide film 103 at the surface is removed by CMP techniques, thereby planarizing the surface. At this time, the mask material 111 is exposed.

Next, as shown in FIG. 10D, after the exposed mask material 111 is selectively etched with a chemical solution or the like, the exposed surface of the silicon oxide film 103 is etched using diluted hydrofluoric acid so as to be as high as the surface of the alumina film 105.

Next, as shown in FIG. 10E, a silicon nitride film 104 to act as a barrier layer 14 is deposited to a thickness of 2 nm on the surface of the alumina film 105 serving as the blocking insulating film 15 and on the surface of the silicon oxide film 103 serving as the element isolation insulating film 13 by ALD techniques using dichlorosilane as a silicon source and ammonia radical as a nitriding agent.

Then, as shown in FIG. 10F, a tantalum nitride film 131 is deposited to a thickness of 10 nm as the control gate electrode 16 by ALD techniques using pentadimethylamino tantalum (PDMAT) and ammonia radical. On the tantalum nitride film 131, a tungsten silicide layer 132 is deposited by CVD techniques. Thereafter, a nonvolatile semiconductor memory is completed using the same method as explained above.

As described above, in the nonvolatile semiconductor memory device of the third embodiment, since the charge storage layer 12 is isolated at the cross section of FIG. 8 in the channel width direction by the element isolation insulating film 13, a fluctuation in the threshold voltage of the memory cells caused by charge diffusion between adjacent cells can be suppressed. The barrier layer 14 provided at the interface between the element isolation insulating film 13 and the control gate electrode 16 can suppress the diffusion of impurities into the STI, even if the source gas including carbon or nitrogen was used, during the control gate electrode layer (including elemental aluminum or a transition metal, such as tantalum, tungsten, or titanium) deposition. Accordingly, the same effect as that of the first embodiment can be obtained.

In the third embodiment, the barrier layer 14 composed of a silicon nitride film has been formed at the interface between the control gate electrode 16 and the element isolation insulating film 13 by ALD techniques. As the nitride film of the barrier layer 14 gets thicker, the diffusion barrier properties of impurities, such as carbon or nitrogen, improve more at the time of forming the control gate electrode. However, when the film thickness is 3 nm or more, charges are trapped in the interface barrier nitride film layer at the time of a write/erase operation, with the result that the write/erase characteristics of the memory cells and the charge retention characteristic deteriorate. Therefore, it is desirable that the thickness of the silicon nitride film of the barrier layer 14 should be not less than 1 nm and not greater than 3 nm.

While in the manufacturing method, the silicon nitride film 104 acting as the barrier layer 14 has been deposited by ALD techniques using dichlorosilane as a silicon source and ammonia radical as a nitriding agent, the silicon nitride film 104 may be deposited using other raw material gases. The ALD techniques are favorable as a method of forming an interface barrier silicon nitride film layer in the third embodiment since the film thickness can be controlled accurately even in the thin-film region and the film can be deposited so as to produce a good morphology even on the element isolation insulating film 13. The same effect can be produced even by forming the silicon nitride film by another method, such as LPCVD techniques or radical nitriding techniques. Moreover, the barrier layer 14 is not necessarily a silicon nitride film. For instance, if a silicon oxide film whose density is higher than the silicon oxide film of the element isolation insulating film 13 is used as the barrier layer 14 as shown in the second embodiment, this prevents impurities in the source gas from diffusing into the element isolation insulating film in forming the control gate electrode, which produces the same effect.

(Modification)

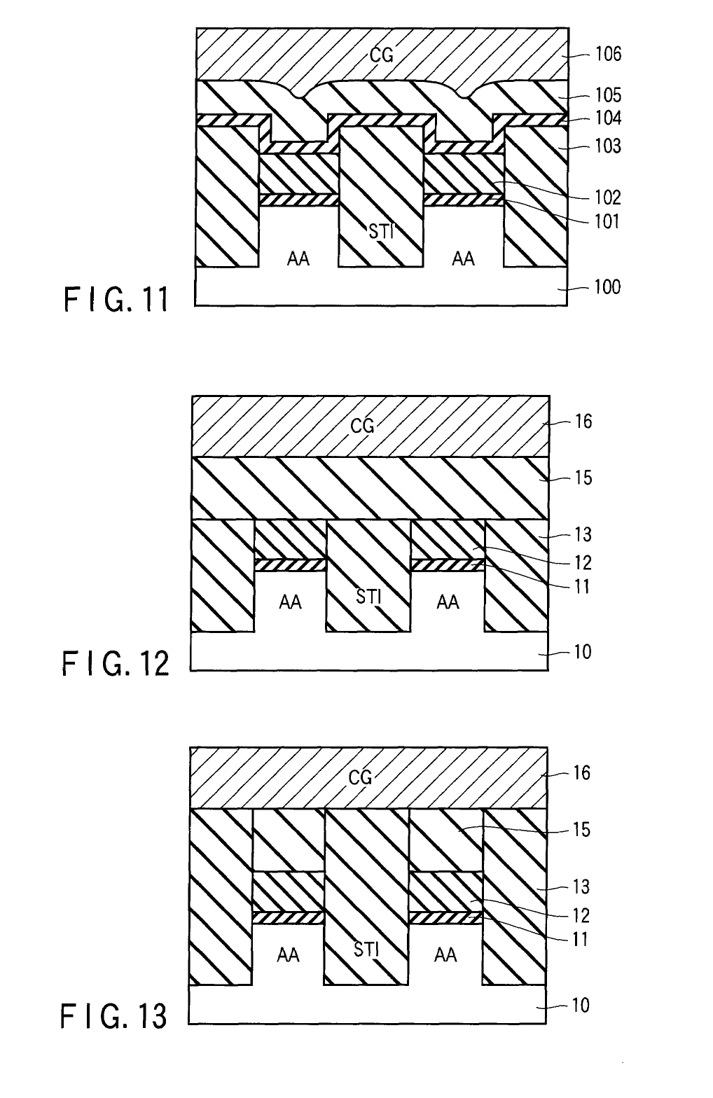

The invention is not limited to the above embodiments. While in the first and second embodiments, the element isolation insulating film has been etched so as to be as high as the charge storage layer, with the blocking insulating film being horizontal in the word line direction, the first and second embodiments may be applied to a case where the surface of the element isolation insulating film and that of the charge storage layer are not horizontal in the word line direction. For instance, the first embodiment may be applied to the structure as shown in FIG. 11.

In the process shown in FIG. 3D, the silicon oxide film 103 is left higher than the silicon nitride film 102, forming a step. In this state, a silicon nitride film 104 acting as a barrier layer, an alumina film 105 acting as a blocking insulating film, and a conducting layer 106 acting as a control gate electrode are formed. Then, because of the effect of the step, the underside of the control gate electrode is formed so as to project downward at a center portion of the unit gate structure.

With such a structure, an electric field at the central part of the unit gate structure is enhanced. The sidewall portion of the memory cell may have been damaged by etching process. Therefore, Nonuse of the damaged part prevents the device characteristics from degradation.

While in the third embodiment, the barrier layer has been formed between the element isolation insulating film and the blocking insulating film or between the element isolation insulating film and the control gate electrode, the barrier layer may be formed only between the element isolation insulating film and the control gate because the diffusion of impurities, such as carbon or nitrogen, from the control gate electrode into the element isolation insulating film has only to be suppressed. Moreover, in the third embodiment, too, a silicon oxide film whose density is higher than the silicon oxide film constituting the element isolation insulating film may be used as the barrier layer as shown in the second embodiment.

Furthermore, while in the third embodiment, a silicon oxide film or a silicon nitride film whose density is higher than the silicon oxide film constituting the element isolation insulating film has been used as the barrier layer, a silicon oxynitride film may be used in place of them.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
a semiconductor substrate with an element forming region;
a charge storage layer which is composed of an insulating film and which is provided on a tunnel insulating film above the element forming region of the substrate;
a blocking insulating film which is provided on the charge storage layer;
an element isolation insulating film which is buried in the substrate so as to isolate adjacent element forming regions and which is provided so as to isolate the charge storage layer or the charge storage layer and blocking insulating film;
a control gate which is provided on the blocking insulating film; and
a barrier layer which is provided between the element isolation insulating film and the blocking insulating film or the control gate and which is composed of at least one of a silicon nitride film, a silicon oxynitride film, and a silicon oxide film each having a higher density than that of the element isolation insulating film.

2. The nonvolatile semiconductor memory device according to claim 1, wherein the element isolation insulating film is formed so as to isolate the charge storage layer, and
the blocking insulating film is formed on the charge storage layer and element isolation insulating film.

3. The nonvolatile semiconductor memory device according to claim 2, wherein the barrier layer is formed between the charge storage layer and the blocking insulating film, and between the element isolation insulating film and the blocking insulating film.

4. The nonvolatile semiconductor memory device according to claim 1, wherein the element isolation insulating film is formed so as to isolate the charge storage layer and blocking insulating film, and the control gate is formed on the blocking insulating film and element isolation insulating film.

5. The nonvolatile semiconductor memory device according to claim 4, wherein the barrier layer is formed between the blocking insulating film and the control gate, and between the element isolation insulating film and the control gate.

6. The nonvolatile semiconductor memory device according to claim 1, wherein the element isolation insulating film is a silicon oxide film.

7. The nonvolatile semiconductor memory device according to claim 1, wherein the charge storage layer is a silicon nitride film.

8. The nonvolatile semiconductor memory device according to claim 1, wherein the blocking insulating film is an alumina film.

9. The nonvolatile semiconductor memory device according to claim 1, wherein the gate electrode is a tungsten silicide film.

10. The nonvolatile semiconductor memory device according to claim 2, wherein the upper surface of the element isolation insulating film is higher than the upper surface of the charge storage layer.

11. A nonvolatile semiconductor memory device manufacturing method comprising:
forming a tunnel insulating film on a semiconductor substrate;
forming a charge storage layer composed of an insulating film on the tunnel insulating film;
not only selectively etching the charge storage layer and tunnel insulating film between adjacent element forming regions of the substrate but also etching the surface part of the substrate, thereby forming an element isolation trench;
forming an element isolation insulating film so as to fill up the element isolation trench;
forming on at least the element isolation insulating film a barrier layer composed of at least one of a silicon nitride film, a silicon oxynitride film, and a silicon oxide film which has a higher density than that of the element isolation insulating film;
forming on the element isolation insulating film and charge storage layer, a blocking insulating film at the interface with at least the element isolation insulating film so as to sandwich the barrier layer between the element isolation insulating film and the blocking insulating film; and
forming a control gate on the blocking insulating film.

12. The nonvolatile semiconductor memory device manufacturing method according to claim 11, wherein the barrier layer is formed on the element isolation insulating film and charge storage layer and
the blocking insulating film is formed on the barrier layer.

13. The nonvolatile semiconductor memory device manufacturing method according to claim 11, wherein the barrier layer is formed only on the element isolation insulating film and
the blocking insulating film is formed on the barrier layer and charge storage layer.

14. A nonvolatile semiconductor memory device manufacturing method comprising:
forming a tunnel insulating film on a semiconductor substrate;
forming a charge storage layer composed of an insulating film on the tunnel insulating film;
forming a blocking insulating film on the charge storage layer;
not only selectively etching the blocking insulating film, charge storage layer, and tunnel insulating film between adjacent element forming regions of the substrate but also etching the surface part of the substrate, thereby forming an element isolation trench;
forming an element isolation insulating film so as to fill up the element isolation trench;
forming on at least the element isolation insulating film a barrier layer composed of at least one of a silicon nitride film, a silicon oxynitride film, and a silicon oxide film which has a higher density than that of the element isolation insulating film; and
forming on the element isolation insulating film and blocking insulating film, a control gate film at the interface with at least the element isolation insulating film so as to sandwich the barrier layer between the element isolation insulating film and the control gate.

15. The nonvolatile semiconductor memory device manufacturing method according to claim 14, wherein the barrier layer is formed on the element isolation insulating film and blocking insulating film and
the control gate is formed on the barrier layer.

16. The nonvolatile semiconductor memory device manufacturing method according to claim 14, wherein the barrier layer is formed only on the element isolation insulating film and
the control gate is formed on the barrier layer and blocking insulating film.
